(19) United States
(12) Patent Application Publication
(10) Pub. No.: US 2010/0007400 A1
(43) Pub. Date: Jan. 14, 2010

(54) POWER SUPPLY CIRCUIT FOR PULSE WIDTH MODULATION CONTROLLER

(75) Inventors: HUA ZOU, Shenzhen City (CN); FENG-LONG HE, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/192,088

(22) Filed: Aug. 14, 2008

(30) Foreign Application Priority Data
Jul. 8, 2008 (CN) 200810302655.9

(51) Int. Cl. H03K 17/00

(52) U.S. Cl. 327/407

(57) ABSTRACT

A power supply circuit for a pulse width modulation controller includes a first resistor and an electric switch having first, second, and third terminals. The first terminal is capable of receiving a control signal of a computer. The second terminal is connected to a stand-by power supply of the computer. The third terminal is connected to the pulse width modulation controller via the first resistor.

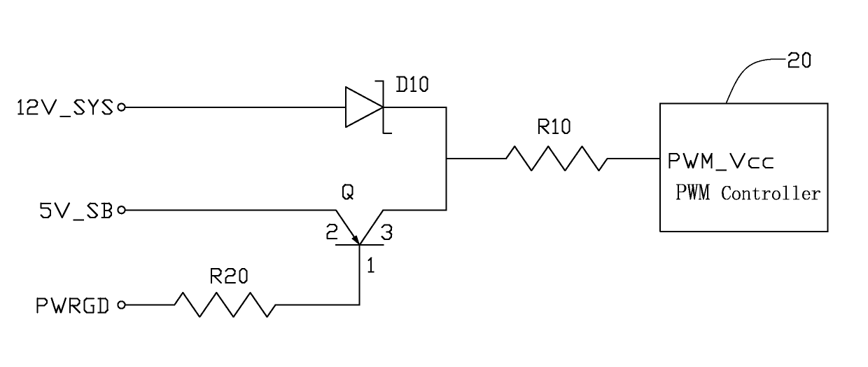

### BACKGROUND

1. Field of the Invention

The present invention relates to power supply circuits and, particularly to a power supply circuit for a pulse width modulation (PWM) controller on a motherboard.

2. Description of Related Art

Switched-mode power supplies such as PWM controllers are being increasingly used in computers to provide a number of precisely regulated output voltages to power various integrated circuits and other components contained within the computers. Input voltages of the PWM controllers are provided by a computer power supply. Computer users often cannot wake their computers from sleep mode because input voltages of the PWM controllers in the computers are often lower than a predetermined value.

What is needed, therefore, is to provide a power supply circuit to wake up a computer from sleep mode.

### BRIEF DESCRIPTION OF THE DRAWING

The drawing is a circuit diagram of a power supply circuit for a PWM controller according to an embodiment of the present invention.

### DETAILED DESCRIPTION

Referring to the drawing, a power supply circuit for a PWM controller 20 in a computer according to an embodiment of the present invention includes a diode D10, an electric switch Q, first and second resistors R10 and R20. The anode of the diode D10 is connected to a system power supply 12_SYS of the computer. The cathode of the diode D10 is connected to a power input terminal PWM_Vcc of the PWM controller 20 via the resistor R10. The electric switch Q includes first, second, and third terminals 1, 2 and 3. The first electric switch terminal 1 is configured for receiving a power good (PWRGD) signal of the computer via the second resistor R20. The second electric switch terminal 2 is connected to a stand-by power supply 5V_SB of the computer. The third electric switch terminal 3 is connected to the cathode of the diode D10. In this embodiment, the type of the PWM controller 20 is RT9214. The electric switch Q is a P-channel metallic oxide semiconductor field effect (PMOS) transistor or a positive-negative-positive (PNP) transistor. The first to third electric switch terminals 1, 2 and 3 are the gate, the drain, and the source of the PMOS transistor or the base, the collector, and the emitter of the PNP transistor respectively. When the power input terminal PWM_Vcc receives a voltage higher than a predetermined value, for example, 4.75V, the computer can be wakened from a sleep mode.

When the computer is wakened from the sleep mode, the system power supply 12V_SYS outputs no voltage. The PWRGD signal is at a low level, and the electric switch Q is on. The voltage difference between the terminals 2 and 3 is nearly 0V. The stand-by power supply 5V_SB provides an input voltage to the PWM controller 20 via the switch Q and the first resistor R10. The voltage at the power input terminal PWM_Vcc is greater than 4.75V because no voltage is dropped across the electric switch 20 when it is on.

When the computer is working normally, the PWRGD signal is at a high level, and the electric switch Q is off. The system power supply 12V_SYS provides the input voltage to the PWM controller 20 via the diode 10 and the second resistor 20.

The embodiment is chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A power supply circuit for a pulse width modulation controller, comprising:
a first resistor; and
an electric switch comprising:
a first electric switch terminal capable of receiving a control signal of a computer;
a second electric switch terminal connected to a stand-by power supply of the computer; and
a third electric switch terminal connected to the pulse width modulation controller via the first resistor.

2. The circuit as claimed in claim 1, further comprising a diode; wherein the diode anode is connected to a system power supply of the computer, and the diode cathode is connected to the third electric switch terminal.

3. The circuit as claimed in claim 1, wherein the type of the pulse width modulation controller is RT9214.

4. The circuit as claimed in claim 1, further comprising a second resistor, wherein the first electric switch terminal receives the control signal via the second resistor.

5. The circuit as claimed in claim 1, wherein the electric switch is a positive-negative-positive transistor, and the first, second and third electric switch terminals are the base, the collector, and the emitter respectively.

6. The circuit as claimed in claim 1, wherein the electric switch is a P-channel metallic oxide semiconductor field effect transistor, and the first, second and third electric switch terminals are the gate, the drain, and the source respectively.

7. The circuit as claimed in claim 1, wherein the control signal is a power good signal of the computer.

8. A method for supplying power to a pulse width modulation controller, comprising:
providing a first resistor and an electric switch, wherein the switch comprises first, second and third terminals; the first terminal is connected to a computer to receive a control signal, the second terminal is connected to a stand-by power supply of the computer, and the third terminal is connected to the pulse width modulation controller via the first resistor;
receiving a control signal of the computer by the first terminal;
supplying power to the pulse width modulation controller via the third terminal and first resistor on a condition that the control signal is at a low level when the computer is being wakened.

9. The method as claimed in claim 8, further comprising
providing a diode;
connecting the diode anode to a system power supply of the computer; and
connecting the diode cathode to the third terminal.

10. The method as claimed in claim 8, wherein the type of the pulse width modulation controller is RT9214.

11. The method as claimed in claim 8, further comprising providing a second resistor, wherein the first terminal receives the control signal via the second resistor.

12. The method as claimed in claim 8, wherein the electric switch is a positive-negative-positive transistor, and the first, second and third terminals are the base, the collector, and the emitter respectively.

13. The method as claimed in claim 8, wherein the electric switch is a P-channel metallic oxide semiconductor field effect transistor, and the first, second and third terminals are the gate, the drain, and the source respectively

14. The method as claimed in claim 8, wherein the control signal is a power good signal of the computer.
